(19) United States
(12) Patent Application Publication
(10) Pub. No.: US 2024/0373591 A1
(43) Pub. Date: Nov. 7, 2024

(54) TRANSMISSION ELECTRON MICROSCOPE

(71) Applicant: SAMSUNG ELECTRONICS CO., LTD., Suwon-si (KR)

(72) Inventors: Daesung Moon, Suwon-si (KR); Jihyun Lee, Suwon-si (KR); Jaeryong Jung, Suwon-si (KR); Jaesun Cho, Suwon-si (KR); Yoonsang Jung, Suwon-si (KR); Youngjun Kim, Suwon-si (KR); Seonung Yeom, Suwon-si (KR); Yewon Lim, Suwon-si (KR); Sunil Hyun, Suwon-si (KR)

(73) Assignee: SAMSUNG ELECTRONICS CO., LTD., Suwon-si (KR)

(21) Appl. No.: 18/648,045

(22) Filed: Apr. 26, 2024

(30) Foreign Application Priority Data
May 4, 2023 (KR) 10-2023-0058769
Jun. 29, 2023 (KR) 10-2023-0084529

(51) Int. Cl. H05K 7/20; H01J 37/141; H01J 37/18; H01J 37/26

(52) U.S. Cl. CPC H05K 7/20336; H01J 37/141; H01J 37/18; H01J 37/26; H05K 7/203; H05K 7/20318; H01J 2237/0216

(57) ABSTRACT

A transmission electron microscope includes a specimen chamber, a heat exchange bridge extending outward from a side wall of the specimen chamber, and a heat exchange connector including a heat exchange tube provided around a first portion of the heat exchange bridge, and a housing sealing the first portion of the heat exchange bridge and the heat exchange tube from an outside of the heat exchange connector.

### CROSS-REFERENCE TO RELATED APPLICATION

This application is based on and claims priority under 35 U.S.C. § 119 to Korean Patent Application No. 10-2023-0058769, filed on May 4, 2023, and Korean Patent Application No. 10-2023-0084529, filed on Jun. 29, 2023, in the Korean Intellectual Property Office, the disclosures of which are incorporated by reference herein in their entireties.

### BACKGROUND

The present disclosure relates to a transmission electron microscope (TEM), and more particularly, to a TEM including a cooling module.

TEMs, which are a type of electron microscope, are used to directly observe even the atomic structures of specimens by passing electron beams through the specimens to form images of the specimens. TEMs use, as a light source, an electron beam having the properties of waves and the properties of charged particles and capable of theoretically guaranteeing a very high resolution on the level of several picometers when accelerated by a high voltage.

An electron beam traveling along an optical axis inside a column of a TEM may be easily scattered by particles such as water molecules or hydrocarbon compound particles. Thus, various studies have been conducted to maintain a high vacuum in a TEM.

### SUMMARY

Example embodiments provide a transmission electron microscope having high resolution and high operability and configured to reduce an analysis waiting time.

According to an aspect of an example embodiment, a transmission electron microscope includes: a specimen chamber; a heat exchange bridge extending outward from a side wall of the specimen chamber; and a heat exchange connector including a heat exchange tube provided around a first portion of the heat exchange bridge, and a housing sealing the first portion of the heat exchange bridge and the heat exchange tube from an outside of the heat exchange connector.

According to an aspect of an example embodiment, a transmission electron microscope includes: a specimen chamber configured to receive a specimen holder; a heat exchange bridge including: a first portion protruding from an outer wall of the specimen chamber and extending in a horizontal direction, and a second portion contacting the first portion and extending in a vertical direction; a heat exchange connector including a cooling cylinder and a housing, wherein the cooling cylinder includes an inner wall and an outer wall spaced apart from the inner wall, and the housing includes an inner container provided around the cooling cylinder and an outer container provided around the inner container; and a heat exchange tube provided in a space between the inner wall of the cooling cylinder and the outer wall of the cooling cylinder, wherein the second portion of the heat exchange bridge is provided in a cooling space defined by the inner wall of the cooling cylinder.

According to an aspect of an example embodiment, a transmission electron microscope includes: an optical module including a column, a plurality of electromagnetic lenses arranged in a vertical direction within the column, and a specimen chamber between two adjacent electromagnetic lenses from among the plurality of electromagnetic lenses; a vacuum module including a plurality of vacuum pumps connected to the specimen chamber; and a cooling module including a heat exchange connector connected to the specimen chamber, and a cooler body connected to the heat exchange connector, wherein the specimen chamber includes a chamber side wall, and a heat exchange bridge including a first portion protruding outward from the chamber side wall and extending in a first horizontal direction, and a second portion connected to the first portion and extending in the vertical direction, wherein the heat exchange connector includes a housing and a heat exchange tube provided in the housing, wherein the second portion of the heat exchange bridge is provided in a cooling space of the housing, and the heat exchange tube is provided around the second portion of the heat exchange bridge.

### BRIEF DESCRIPTION OF THE DRAWINGS

The above and other aspects and features will be more apparent from the following description of more example embodiments taken in conjunction with the accompanying drawings, in which:

FIG. 1 is a block diagram illustrating a transmission electron microscope according to one or more example embodiments;

FIG. 2 is a cross-sectional view illustrating an optical module of the transmission electron microscope according to one or more example embodiments;

FIG. 3 is a cross-sectional view illustrating a specimen chamber of the optical module according to one or more example embodiments;

FIG. 4 is a plan view illustrating the specimen chamber of the optical module according to one or more example embodiments;

FIG. 5 is a perspective view illustrating the specimen chamber of the optical module and a cooling module according to one or more example embodiments;

FIG. 6 is a cross-sectional view illustrating a heat exchange connector of the cooling module according to one or more example embodiments;

FIG. 7 is a cross-sectional view illustrating a heat exchange connector of the cooling module according to one or more example embodiments; and

FIG. 8 is a cross-sectional view illustrating a heat exchange connector of the cooling module according to one or more example embodiments.

### DETAILED DESCRIPTION

Hereinafter, example embodiments will be described with reference to the accompanying drawings. In the drawings, like reference numerals denote like elements, and repeated descriptions thereof are omitted.

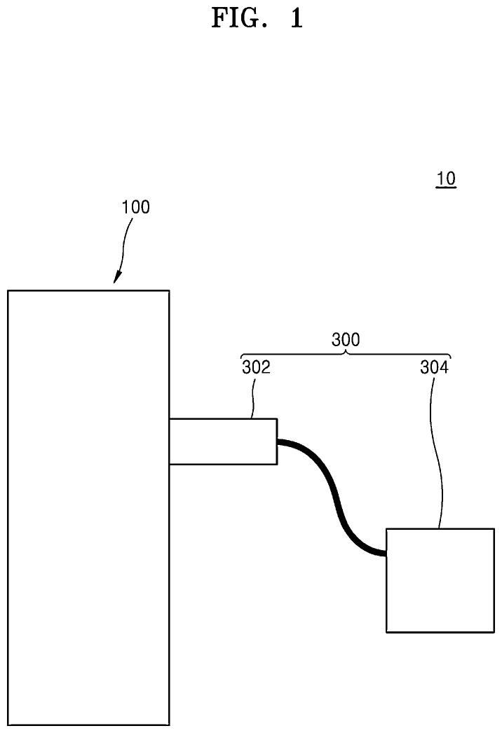

FIG. 1 is a block diagram illustrating a transmission electron microscope 10 according to one or more example embodiments.

Referring to FIG. 1, the transmission electron microscope 10 may include a plurality of lenses, an optical module 100 configured to form an image by emitting an electron beam to pass through a specimen, and a cooling module 300 configured to continuously cool a component of the optical module 100.

According to one or more example embodiments, the cooling module 300 may include a heat exchange connector 302 connected to the optical module 100. The heat exchange connector 302 may be in direct contact with the component of the optical module 100 or may be thermally connected to the component of the optical module 100 to cool the component of the optical module 100.

According to one or more example embodiments, the cooling module 300 may be configured to cool the optical module 100 when the transmission electron microscope 10 is on standby, as well as when the transmission electron microscope 10 is in use. For example, the cooling module 300 may be configured to continuously cool the optical module 100 without interruption during a period of observing a specimen using the transmission electron microscope 10 and a period of replacing the specimen. In addition, the cooling module 300 may be configured to continuously cool the optical module 100 even when the transmission electron microscope 10 is not in use.

According to one or more example embodiments, the cooling module 300 may use a consumable refrigerant to cool the optical module 100. For example, the consumable refrigerant may refer to a refrigerant that is used in direct contact with or around an object to be cooled and that is evaporated and discarded into the air. For example, liquid nitrogen, which is a type of consumable refrigerant, may be used by a method such as a method of immersing an object to be cooled into liquid nitrogen or a method of spraying liquid nitrogen on an object to be cooled, and then the liquid nitrogen may be evaporated by heat exchange with the object and may be discarded (consumed) into the air. It may be inconvenient to use such a consumable refrigerant because it is needed to replace a storage tank of the consumable refrigerant, and it may be burdensome to use a consumable refrigerant without limit to keep the temperature of the optical module 100 at a low level even when the optical module 100 is on standby for the next use. For example, during a standby time for the next use, the optical module 100 may be left unattended, and the temperature of the optical module 100 may rise. In this case, when a specimen is observed using the optical module 100 without lowering the temperature of the optical module 100 back to a certain level, a drift phenomenon in which images of the specimen are not stationary, but move in a specific direction, may occur, causing a decrease in the resolution of the optical module 100. It takes a considerable time to lower the temperature of the optical module 100 to a level at which the optical module 100 has a high resolution, and thus, it is advantageous to always keep the temperature of the optical module 100 at a low level to use the transmission electron microscope 10 at any time.

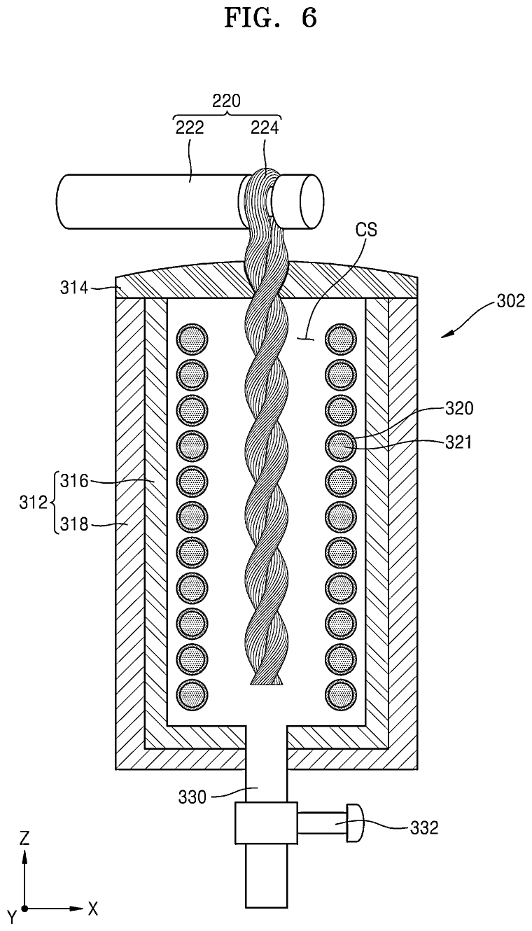

According to one or more example embodiments, the cooling module 300 may be configured to continuously cool the optical module 100 through vaporization and condensation of a refrigerant 321 (refer to FIG. 6) without having to refill the refrigerant 321. According to one or more example embodiments, the refrigerant 321 of the cooling module 300 may cool the optical module 100 while vaporizing in the heat exchange connector 302 that is in contact with the optical module 100, and may then condense in a cooler body 304 for reuse. For example, the cooler body 304 may receive power from an external source and may use the power as energy for condensing the refrigerant 321.

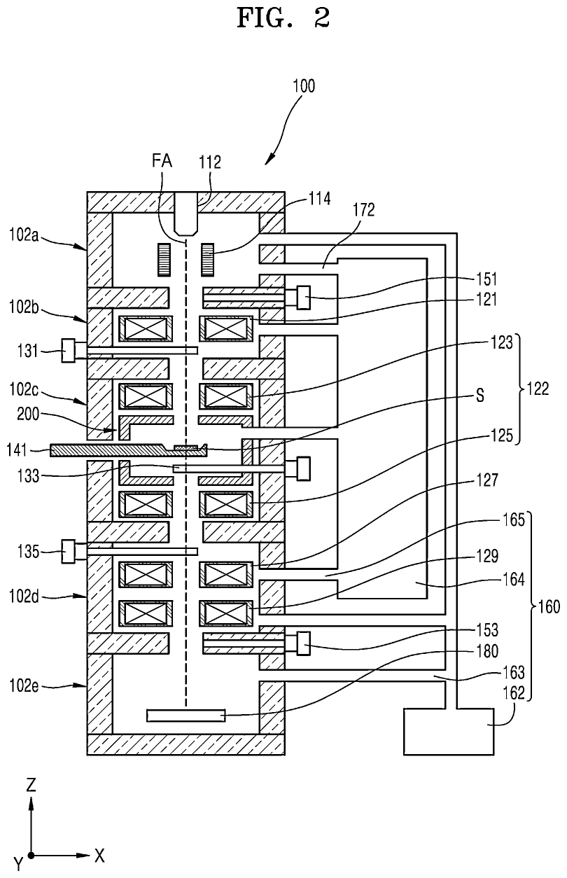

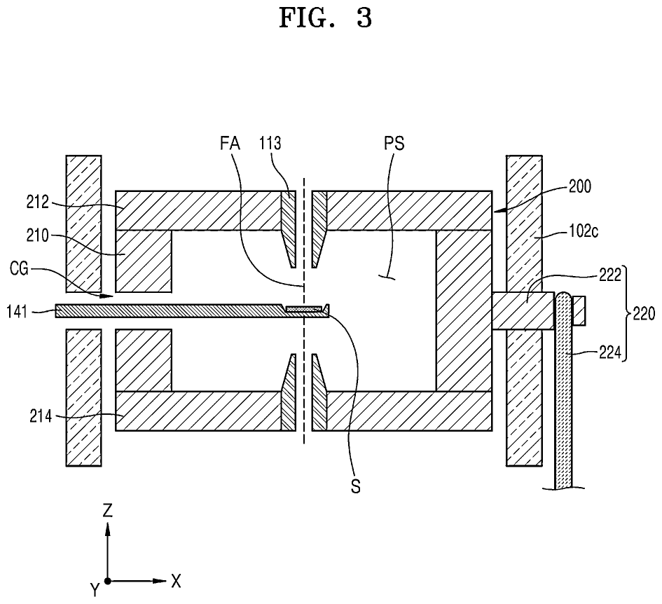

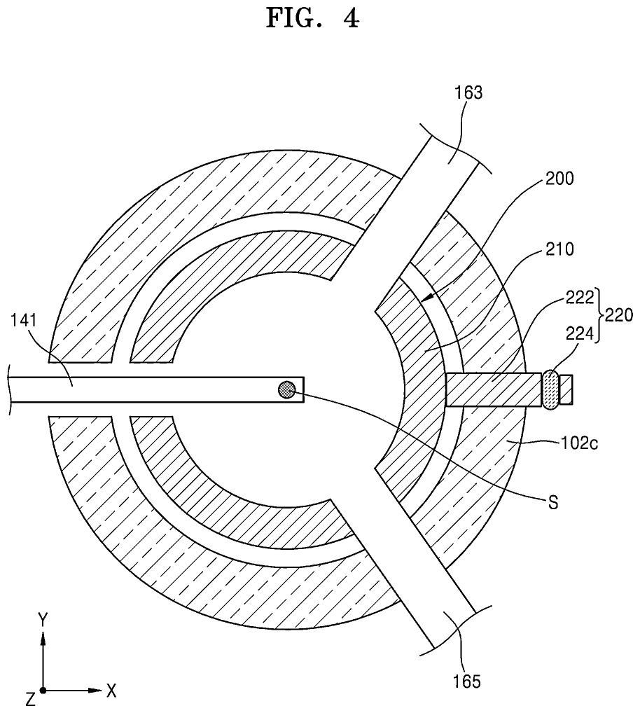

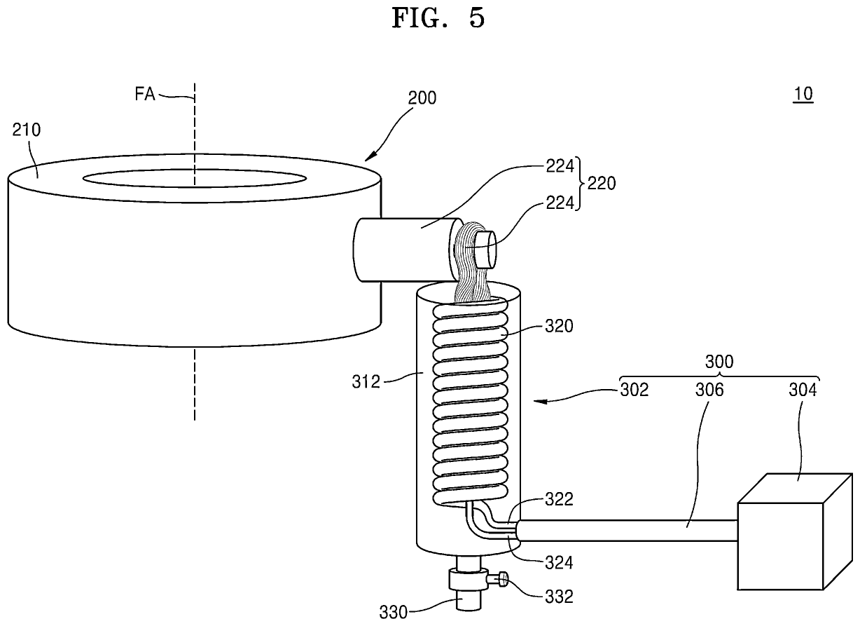

FIG. 2 is a cross-sectional view illustrating the optical module 100 of the transmission electron microscope 10 according to one or more example embodiments. FIG. 3 is a cross-sectional view illustrating a specimen chamber 200 of the optical module 100 according to one or more example embodiments. FIG. 4 is a plan view illustrating the specimen chamber 200 of the optical module 100 according to one or more example embodiments. FIG. 5 is a perspective view illustrating the specimen chamber 200 of the optical module 100 and the cooling module 300 according to one or more example embodiments. FIG. 6 is a cross-sectional view illustrating the heat exchange connector 302 of the cooling module 300 according to one or more example embodiments.

Referring to FIGS. 2, 3, 4, 5 and 6, the optical module 100 may include first, second, third, fourth and fifth columns 102a, 102b, 102c, 102d, and 102e that provide an electron beam path through which an electron beam passes. The first, second, third, fourth and fifth columns 102a, 102b, 102c, 102d, and 102e may be arranged in a line in a vertical direction (a Z direction) along the electron beam path. The first, second, third, fourth and fifth columns 102a, 102b, 102c, 102d, and 102e may be separated from each other by a plurality of plates or housing members that extend in a horizontal direction (an X direction and/or a Y direction) between the first, second, third, fourth and fifth columns 102a, 102b, 102c, 102d, and 102e. For example, the plates or the housing members may include pole pieces, and the pole pieces may include holes extending in the vertical direction (Z direction) to form the electron beam path.

According to one or more example embodiments, an electron gun 112 and an acceleration tube 114 may be disposed in the first column 102a. The electron gun 112 may be configured to generate electrons in an upper portion of the first column 102a to project an electron beam toward a specimen. The electron beam may have an optical axis FA and may travel in the vertical direction (the Z direction). The acceleration tube 114 may include an anode and may be configured to accelerate negatively-charged electrons. For example, electrons emitted from the electron gun 112 may be attracted to the anode by a potential difference, and as a high voltage is applied to the anode, the electrons may be accelerated and may pass through a hole of the accelerator tube 114 at high speed.

According to one or more example embodiments, an accelerated electron beam may pass through a hole formed in a bottom portion of the first column 102a and may sequentially pass through the second to fifth columns 102b, 102c, 102d, and 102e. At least one electromagnetic lens may be disposed in the second, third and fourth columns 102b, 102c, and 102d. For example, the at least one electromagnetic lens may have a cylindrical shape in which an electromagnetic coil is wound. The at least one electromagnetic lens may focus an electron beam on one location according to the property of electrons bending in a magnetic field. For example, when a current is applied to the electromagnetic coil, a circularly symmetric magnetic field may be formed around the optical axis FA of an accelerated electron beam, and thus, the accelerated electron beam traveling along the optical axis FA may be focused while forming a helical trajectory.

According to one or more example embodiments, a condenser lens 121 may be disposed in the second column 102b, an objective lens 122 may be disposed in the third column 102c, and an intermediate lens 127 and a projector lens 129 may be disposed in the fourth column 102d. For example, the condenser lens 121, the objective lens 122, the intermediate lens 127, and the projector lens 129 may form a lens stack of the optical module 100.

According to one or more example embodiments, the specimen chamber 200 may be configured to accommodate a specimen holder 141 and may be disposed in the third column 120c. According to one or more example embodiments, a specimen S may be placed on the specimen holder 141, inserted into the specimen chamber 200 through a gate CG, and placed in the electron beam path through which an accelerated electron beam passes. An electron beam passing through the specimen S may form an image while traveling through the third column 120c. The image may be magnified while passing through the fourth column 120d, and may then be projected onto a fluorescent screen 180 disposed in the fifth column 120e, such that the image may be observed with the naked eye.

According to one or more example embodiments, the condenser lens 121, a condenser aperture 131, and a deflector may be disposed in the second column 102b. The condenser lens 121, the condenser aperture 131, and the deflector may form an illumination system of the optical module 100. Although FIG. 2 illustrates that the illumination system includes one condenser lens 121 and one condenser aperture 131, one or more example embodiments are not limited thereto. For example, the illumination system may independently include one or more condenser lenses 121 and one or more condenser apertures 131.

According to one or more example embodiments, the illumination system may focus an electron beam on a specimen S such that an image of the specimen S may be sufficiently bright at an observation magnification, and may adjust the convergence angle of the electron beam at the observation magnification such that the image of the specimen S may be formed on the fluorescent screen 180. For example, the condenser lens 121 may be a relatively strong lens configured to focus electrons on a specimen S by reducing the spot size of a light source. The deflector may independently control the position and angle of an electron beam at the position of a specimen S, and may maintain an electron beam near a low-aberration center of each of the condenser lens 121, the objective lens 122, the intermediate lens 127, and the projector lens 129.

According to one or more example embodiments, the objective lens 122, the specimen chamber 200, and an objective aperture 133 may be disposed in the third column 102c. According to one or more example embodiments, the objective lens 122 may include a first sub-objective lens 123 disposed above the specimen chamber 200 and a second sub-objective lens 125 disposed below the specimen chamber 200. According to one or more example embodiments, the objective lens 122 may form an image of a specimen S, and the image formed by the objective lens 122 may then be magnified by the intermediate lens 127 and the projector lens 129. Thereafter, the image may be projected on the fluorescent screen 180.

Although FIG. 2 illustrates an example in which the objective lens 122 includes two sub-objective lenses, that is, the first and second sub-objective lenses 123 and 125 respectively disposed above and below the specimen chamber 200, one or more example embodiments are not limited thereto. For example, unlike in the example illustrated in FIG. 2, the optical module 100 may include one or two or more sub-objective lenses that are disposed only above or below the specimen chamber 200.

Referring to FIGS. 2, 3 and 4, the specimen chamber 200 may include: a chamber side wall 210 having a hollow cylindrical shape; and upper and lower covers 212 and 214 respectively having holes along the electron beam path. According to one or more example embodiments, a processing space PS may be provided by the chamber side wall 210, the upper cover 212 covering an upper surface of the chamber side wall 210, and the lower cover 214 covering a lower surface of the chamber side wall 210.

According to one or more example embodiments, a gate CG may be formed in a side of the specimen chamber 200 to allow the specimen holder 141 to enter and exit the specimen chamber 200 through the chamber gate SHO. For example, the chamber gate SHO may be openable and closable. When observing a specimen S, the inside of the third column 102c and the inside of the specimen chamber 200 may be maintained in a vacuum. The chamber gate SHO may be opened when a specimen S is brought into and out of the specimen chamber 200, and may remain closed when an image of the specimen S is projected and when the specimen chamber 200 stands by after the specimen S is taken out of the specimen chamber 200.

According to one or more example embodiments, a specimen S may be mounted on the specimen holder 141 and placed in the electron beam path. For example, the specimen S may be disposed in the processing space PS to overlap the optical axis FA of an electron beam, and the electron beam may pass through the specimen S to form an image of the specimen S.

For example, a specimen S may be pretreated such that the specimen S may be easily observed using the transmission electron microscope 10, and then, the specimen S may be inserted into the specimen chamber 200. Examples of a specimen pretreatment method may include a nano-powder dispersion method, an ion milling method, a focused ion beam method, a jet polishing method, and an ultramicrotome method. However, one or more example embodiments are not limited thereto.

In one or more example embodiments, a pair of pole pieces 113 may be mounted on the upper cover 212 and the lower cover 214 of the specimen chamber 200. The pair of pole pieces 113 may each have a hole extending in the vertical direction (Z direction) and providing a path for an electron beam. For example, the pair of pole pieces 113 may be provided apart from each other in the vertical direction (Z direction), and the specimen holder 141 and a specimen S placed on the specimen holder 141 may be placed between the pair of hole pieces 113.

For example, the pair of pole pieces 113 may include an upper pole piece 113 formed in one piece with the first sub-objective lens 123 to project an electron beam onto a specimen S through the upper pole piece 113. The pair of pole pieces 113 may include a lower pole piece 113 formed in one piece with the second sub-objective lens 125 to discharge an electron beam to the fourth column 102d through the lower pole piece 113 after the electron beam passes through a specimen S.

Although FIGS. 2 and 3 illustrate that the processing space PS is provided by the chamber side wall 210, the upper cover 212 covering the upper surface of the chamber side wall 210, and the lower cover 214 covering the lower surface of the chamber side wall 210, one or more example embodiments are not limited thereto. For example, according to one or more example embodiments the upper surface of the chamber side wall 210 of the specimen chamber 200 may be covered by a lower surface of the first sub-objective lens 123, and the lower surface of the chamber side wall 210 of the specimen chamber 200 may be covered by an upper surface of the second sub-objective lens 125. In this case, the processing space PS may be provided by the chamber side wall 210, the lower surface of the first sub-objective lens 123, and the upper surface of the second sub-objective lens 125.

Although not shown in FIGS. 3 and 4, the objective aperture 133 may be disposed below the specimen holder 141 as shown in FIG. 2. Although FIG. 2 illustrates that the objective aperture 133 is disposed in the specimen chamber 200 and is located between the specimen holder 141 and the second sub-objective lens 125 in the vertical direction (Z direction), one or more example embodiments are not limited thereto. For example, the objective aperture 133 may be disposed outside the specimen chamber 200 or may be disposed at a vertical level lower than the second sub-objective lens 125.

According to one or more example embodiments, a selective area aperture 135, the intermediate lens 127, and the projector lens 129 may be disposed in the fourth column 102d. The selective area aperture 135 may be disposed between the objective lens 122 and the intermediate lens 127 in the vertical direction (Z direction). For example, the objective aperture 133 may be disposed on a back focal plane of the objective lens 122, and the selective area aperture 135 may be disposed on an image plane of the objective lens 122.

According to one or more example embodiments, the intermediate lens 127 and the projector lens 129 may enlarge an image formed by the objective lens 122 and may project the image onto the fluorescent screen 180. Although FIG. 2 illustrates that the optical module 100 includes one intermediate lens 127 and one projector lens 129, one or more example embodiments are not limited thereto. For example, according to one or more example embodiments, the optical module 100 may independently include two or more intermediate lenses 127 and two or more projector lenses 129. According to one or more example embodiments, the selective area aperture 135, the intermediate lens 127, and the projector lens 129 may form an imaging-projection system of the optical module 100.

According to one or more example embodiments, the fluorescent screen 180 may be disposed in the fifth column 102e, and a user of the transmission electron microscope 10 may observe a specimen S through an image of the specimen S formed on the fluorescent screen 180. For example, the fluorescent screen 180 may include a metal plate coated with a fluorescent material. The fluorescent screen 180 may have a function of converting the contrast of an electron beam such that the electron beam may be observed with the naked eye. Although not shown in FIG. 2, an optical microscope for observing an image formed on the fluorescent screen 180 and a charge-coupled device (CCD) camera for capturing the image may be disposed in the fifth column 102e. According to one or more example embodiments, the fluorescent screen 180, the optical microscope, and the CCD camera may form a recording system of the optical module 100.

According to one or more example embodiments, the transmission electron microscope 10 may include a vacuum module 160 connected to the optical module 100 to form a near-vacuum environment in the optical module 100. The vacuum module 160 may have a function of removing impurities from the electron beam path, and thus, the resolution of the transmission electron microscope 10 may be improved.

According to one or more example embodiments, the vacuum module 160 may include a plurality of vacuum pumps. For example, the vacuum module 160 may include a first pump 162 for discharging air from the optical module 100 and a second pump 164 for adsorbing residual ions from the optical module 100. Examples of the first pump 162 may include a rotary pump, a diffusion pump, a turbomolecular pump, and combinations thereof. However, the first pump 162 is not limited to the examples. For example, according to one or more example embodiments, the second pump 164 may include an ion getter pump.

According to one or more example embodiments, the first pump 162 may lower the inside pressure of the optical module 100 to a range of atmospheric pressure to about 10⁻⁵ Pa, and the second pump 164 may lower the inside pressure of the optical module 100 to a range of about 10⁻⁵ Pa to about 10⁻⁹ Pa to maintain a high vacuum state in each of the first, second, third, fourth and fifth columns 102a, 102b, 102c, 102d, and 102e of the optical module 100. For example, the second pump 164 may include a magnetic material capable of generating an electric field and may thus adsorb fine particles or ions from the inside of the optical module 100.

In one or more example embodiments, a vacuum environment may be formed in the optical module 100 by using the first pump 162 within a range of atmospheric pressure to a relatively low vacuum pressure, and using the second pump 164 within a high vacuum pressure range of about 10⁻⁵ Pa or lower. In one or more example embodiments, the first pump 162 and the second pump 164 may be used together at the same time or may be separately used at different times.

According to one or more example embodiments, the first pump 162 may be connected to the optical module 100 through a first pump pipe 163, and the second pump 164 may be connected to the optical module 100 through a second pump pipe 165. Although FIG. 2 illustrates that the first pump 162 is connected only to the first column 102a, the fourth column 102d, and the fifth column 102e, one or more example embodiments are not limited thereto. For example, according to one or more example embodiments, the first pump 162 may also be connected to the second column 102b and the third column 102c. Furthermore, unlike in the example shown in FIG. 2, according to one or more example embodiments, the second pump 164 may also be connected to the fifth column 102e.

Referring to FIG. 4, the first pump 162 and the second pump 164 may be directly connected to the specimen chamber 200 through the first pump pipe 163 and the second pump pipe 165, respectively. According to one or more example embodiments, the first pump 162 and the second pump 164 may be directly connected to the specimen chamber 200 to induce and maintain a high vacuum inside the specimen chamber 200.

According to one or more example embodiments, the optical module 100 may include a first valve 151 and a second valve 153 that are disposed in the electron beam path to allow an electron beam to pass through the electron beam path or block an electron beam.

According to one or more example embodiments, the first valve 151 and the second valve 153 may be respectively disposed above and below the specimen chamber 200. For example, the first valve 151 may be disposed at a higher vertical level than the specimen chamber 200, and the second valve 153 may be disposed at a lower vertical level than the specimen chamber 200.

In one or more example embodiments, the first valve 151 may be disposed between the first column 102a and the second column 102b in the vertical direction (Z direction), and the second valve 153 may be disposed between the fourth column 102d and the fifth column 102e in the vertical direction (Z direction). The first valve 151 and the second valve 153 may be used as barrier structures for separating spaces from each other inside the optical module 100.

For example, when the first valve 151 is closed, an electron beam emitted from the electron gun 112 toward the fluorescent screen 180 may be blocked by the first valve 151 and, thus, the electron beam may not proceed into the second column 102b. For example, when the first valve 151 is opened and the second valve 153 is closed, an electron beam may proceed into the second, third and fourth columns 102b, 102c, and 102d, but may not proceed into the fifth column 120e because the second valve 153 blocks the electron beam. For example, when the first valve 151 and the second valve 153 are closed together, a vacuum pressure inside the second, third and fourth columns 102b and 102c that are spaces provided by the first valve 151 and the second valve 153 may be controlled independently of each of the first column 102a and the fifth column 102e.

According to one or more example embodiments, when a specimen S is brought into/out of the specimen chamber 200, the first valve 151 and the second valve 153 may be opened/closed together. FIG. 2 shows a state in which both the first valve 151 and the second valve 153 are open. The first, second, third, fourth and fifth columns 102a, 102b, 102c, 102d, and 102e of the optical module 100 may be maintained in a high vacuum as described above, and a specimen S may be replaced by moving the specimen holder 141 outward from the third column 102c, mounting a new specimen S on the specimen holder 141, and moving the sample holder 141 into the third column 102c. At this time, ambient air and foreign substances may be introduced into the third column 102c and the specimen chamber 200. According to one or more example embodiments, when a specimen S and the sample holder 141 are taken into or out of the optical module 100, the first valve 151 and the second valve 153 may be closed to separate the first column 102a and the fifth column 102e from the second, third and fourth columns 102b, 102c, and 102d, and thus a vacuum environment inside each of the first column 102a and the fifth column 102e may not be affected by external agents. The first valve 151 and the second valve 153 may be opened together again to observe a new specimen S, and in this case, an electron beam may proceed to the fluorescent screen 180 without being blocked.

FIG. 2 illustrates that the first valve 151 is disposed between the first column 102a and the second column 102b in the vertical direction (Z direction), and the second valve 153 is disposed between the fourth column 102d and the fifth column 102d in the vertical direction (Z direction). However, one or more example embodiments are not limited thereto. For example, according to one or more example embodiments, the first valve 151 may be disposed between the second column 102b and the third column 102c in the vertical direction (Z direction), and the second valve 153 may be disposed between the third column 102c and the fourth column 102d in the vertical direction (Z direction). In this case, a vacuum environment in the third column 102c may be controlled independent of the first and second columns 102a and 102b and the fourth and fifth columns 102d and 102e.

Referring to FIGS. 3, 4, 5 and 6, a heat exchange bridge 220 may be connected to the chamber side wall 210. According to one or more example embodiments, the optical module 100 may be cooled in a state in which the optical module 100 is connected to the cooling module 300 through the heat exchange bridge 220 extending from the specimen chamber 200. For example, the heat exchange connector 302 of the cooling module 300 may be configured to be thermally connected to the heat exchange bridge 220 to cool the specimen chamber 200 of the optical module 100. According to one or more example embodiments, heat absorbed from the specimen chamber 200 through the heat exchange connector 302 may be transferred to the cooler body 304. According to one or more example embodiments, the cooler body 304 may be configured to absorb thermal energy of the heat exchange connector 302 by using electrical energy.

According to one or more example embodiments, the heat exchange bridge 220 may include a first extension portion 222 and a second extension portion 224. The first extension portion 222 may protrude from an outer surface of the chamber side wall 210. The second extension portion 224 may be connected to and in contact with the first extension portion 222 and may be accommodated in the heat exchange connector 302 in contact with the heat exchange connector 302. In one or more example embodiments, the first extension portion 222 may be formed in one piece with the chamber side wall 210 and may protrude outward through the third column 102c. According to one or more example embodiments, the specimen chamber 200 may include the chamber side wall 210 and the heat exchange bridge 220 protruding from the outer surface of the chamber side wall 210. In one or more example embodiments, an end of the second extension portion 224 may be connected to the first extension portion 222, and the other end of the second extension portion 224 may be accommodated in the heat exchange connector 302.

For example, the first extension portion 222 may protrude from the outer surface of the chamber side wall 210 and extend in a first horizontal direction (X direction), and the second extension portion 224 may be in contact with an end of the first extension portion 222 and may extend in the vertical direction (Z direction).

In one or more example embodiments, the first extension portion 222 and the second extension portion 224 of the heat exchange bridge 220 may include a material having high thermal conductivity. For example, the first extension portion 222 and the second extension portion 224 may include copper (Cu), nickel (Ni), gold (Au), silver (Ag), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga), ruthenium (Ru), or an alloy thereof. However, one or more example embodiments are not limited thereto.

According to one or more example embodiments, the first extension portion 222 and the chamber side wall 210 of the specimen chamber 200 may be enclosed by a heat insulating cover to prevent transfer of external heat to the processing space PS of the specimen chamber 200.

In one or more example embodiments, the second extension portion 224 may be configured to be inserted into the heat exchange connector 302 and to dissipate heat from the specimen chamber 200 to the heat exchange connector 302. In one or more example embodiments, a portion of the second extension portion 224 inserted into the heat exchange connector 302 may have a large surface area. For example, the second extension portion 224 may have a coil bundle shape and may include a material having high thermal conductivity.

According to one or more example embodiments, the heat exchange bridge 220 may transfer heat from the specimen chamber 200 to the heat exchange connector 302 through the first extension portion 222 connected to the specimen chamber 200 and the second extension portion 224 connected to the heat exchange connector 302. External agents may enter the processing space PS of the specimen chamber 200 when a specimen S is brought into or out of the specimen chamber 200, and thus, it may be strictly required to maintain the specimen chamber 200 in a high vacuum state. According to one or more example embodiments, the transmission electron microscope 10 may not only remove air and impurities from the processing space PS by using the vacuum module 160, but may also continuously dissipate heat from the specimen chamber 200 by using the cooling module 300, thereby maintaining the processing space PS in a high vacuum. For example, as heat is dissipated from the specimen chamber 200 to the outside, the pressure of the processing space PS is lowered, and thus the processing space PS may be stably maintained in a high vacuum. In addition, a drift phenomenon occurring due to a temperature increase caused by electron collision may be prevented by lowering the temperature of the processing space PS, thereby implementing a high resolution. For example, the temperature of the processing space PS of the specimen chamber 200 may be maintained within a range of about −275° C. to about 0° C., for example, within a range of about −250° C. to about −50° C.

In one or more example embodiments, energy may be transferred from the chamber side wall 210 of the specimen chamber 200 to the first extension portion 222 by heat conduction, and energy may be transferred from the first extension portion 222 to the second extension portion 224 by heat conduction. In one or more example embodiments, energy may be transferred from the second extension portion 224 to the heat exchange connector 302 by heat conduction and heat convection.

According to one or more example embodiments, the heat exchange connector 302 may include: a housing 312 configured to accommodate the second extension portion 224 of the heat exchange bridge 220; and a cover 314 covering an upper portion of the housing 312. For example, a cooling space CS may be provided by the housing 312 and the cover 314. In one or more example embodiments, the cover 314 may be included in the housing 312 and may be formed in one piece with the housing 312.

In one or more example embodiments, the housing 312 may have a hollow cylinder shape extending in the vertical direction (Z direction). For example, the housing 312 may have a cup structure or a socket structure having a bottom surface, and the second extension portion 224 of the heat exchange bridge 220 may be inserted into the housing 312 and may extend in the vertical direction (Z direction). At least a portion of the second extension portion 224 may be disposed in the cooling space CS sealed by the housing 312 and the cover 314 to transfer heat to the heat exchange connector 302. For example, the second extension portion 224 may pass through the cover 314 and extend into the cooling space CS.

Although FIGS. 5 and 6 illustrate that a portion of the second extension portion 224 of the heat exchange bridge 220 is exposed to the outside of the heat exchange connector 302, one or more example embodiments are not limited thereto. For example, the cover 314 may cover contact portions of the first extension portion 222 and the second extension portion 224 of the heat exchange bridge 220, and in this case, the second extension portion 224 may be entirely accommodated in the cooling space CS of the heat exchange connector 302.

According to one or more example embodiments, the heat exchange connector 302 may include a heat exchange tube 320 configured to absorb heat transferred through the heat exchange bridge 220. According to one or more example embodiments, the heat exchange tube 320 may be disposed in the cooling space CS together with the second extension portion 224.

According to one or more example embodiments, the heat exchange tube 320 may be connected to a connection hose 306 that penetrates the housing 312. For example, the connection hose 306 may thermally connect the heat exchange tube 320 and the cooler body 304.

In one or more example embodiments, the heat exchange tube 320 may have a tubular shape that is spirally wound along an inner wall of the housing 312. In one or more example embodiments, the second extension portion 224 may be disposed inside the spiral structure of the heat exchange tube 320 and may thus be surrounded by the heat exchange tube 320.

In one or more example embodiments, the refrigerant 321 having a relatively high specific heat may flow in the heat exchange tube 320. In one or more example embodiments, the refrigerant 321 may flow into the heat exchange tube 320 through an inlet 322 and may absorb heat dissipated from the second extension portion 224 while flowing along the spiral structure of the heat exchange tube 320. As the refrigerant 321 absorbs heat, the refrigerant 321 may vaporize and flow to the connection hose 306 through an outlet 324. In one or more example embodiments, the cooler body 304 may include a condenser. The refrigerant 321 in a vapor phase may be collected in the cooler body 304 and may be changed into liquid by the condenser. Thereafter, the refrigerant 321 in a liquid phase may be introduced again into the heat exchange tube 320 through the connection hose 306 and the inlet 322.

In one or more example embodiments, a cooling coil including a metal material may be used instead of the heat exchange tube 320.

According to one or more example embodiments, the cooling module 300 may condense the refrigerant 321 from a vapor phase into a liquid phase by using electrical energy and may reuse the refrigerant 321, and thus, the specimen chamber 200 may be continuously cooled without having to refill or replace the refrigerant 321.

In one or more example embodiments, as illustrated in FIGS. 5 and 6, the second extension portion 224 of the heat exchange bridge 220 may be provided apart from the heat exchange tube 320. For example, the heat exchange tube 320 and the second extension portion 224 may exchange heat by convection. When the cooler body 304 condenses the refrigerant 321 from a vapor phase into a liquid phase, vibration may occur and propagate to the heat exchange tube 320 through the connection hose 306, and thus the heat exchange tube 320 may be negatively affected. According to one or more example embodiments, the second extension portion 224 of the heat exchange bridge 220 may be provided apart from the heat exchange tube 320 and may thus be less affected by vibration. Therefore, transmission of vibration to the specimen chamber 200 may be prevented, and thus, the resolution of the transmission electron microscope 10 may be improved.

In one or more example embodiments, the heat exchange tube 320 may be wrapped with a vibration damping film that absorbs vibration. For example, the vibration damping film may include an elastic polymer material.

In one or more example embodiments, the second extension portion 224 of the heat exchange bridge 220 may include a portion that is in contact with the heat exchange tube 320.

According to one or more example embodiments, the housing 312 may have a multilayer structure. According to one or more example embodiments, the housing 312 may include a first container 316 in an inner portion thereof and a second container 318 surrounding an outer surface of the first container 316. According to one or more example embodiments, an inner wall of the first container 316 may provide the cooling space CS, and an outer wall of the first container 316 may be in contact with the second container 318.

In one or more example embodiments, the first container 316 may be configured to absorb vibration transmitted from the cooler body 304. For example, the first container 316 may include a polymer material. The polymer material may include an elastic body. In one or more example embodiments, the first container 316 may include natural rubber, isoprene rubber, styrene butadiene rubber, acrylonitrile butadiene rubber, butadiene rubber, chloroprene rubber, butyl rubber, ethylene-propylene rubber, silicone rubber, urethane rubber, or a combination thereof. However, one or more example embodiments are not limited thereto.

In one or more example embodiments, the second container 318 may be configured to prevent heat transfer from the outside of the housing 312 to the cooling space CS. In one or more example embodiments, the second container 318 may include an insulating material having a relatively low thermal conductivity. For example, the second container 318 may include a ceramic material such as cordierite, silicone, glass, or an insulating polymer material. One or more example embodiments of the insulating polymer material may include polyurethane, phenolic resin, polystyrene, and combinations thereof. However, one or more example embodiments are not limited thereto.

Although FIG. 6 illustrates that the first container 316 configured to absorb vibration is disposed inside the second container 318, and the second container 318 configured to block external heat is disposed outside the first container 316, one or more example embodiments are not limited thereto. For example, the second container 318 configured to block external heat may be disposed inside the first container 316, and the first container 316 configured to absorb vibration may surround the outside of the second container 318.

According to one or more example embodiments, the heat exchange connector 302 may include a drain pipe 330 connected to the cooling space CS through a lower surface of the housing 312 and a discharge valve 332 connected to the drain pipe 330. According to one or more example embodiments, the drain pipe 330 and the discharge valve 332 may be configured to discharge water that is condensed in the cooling space CS by heat exchange between the heat exchange bridge 220 and the heat exchange tube 320.

According to one or more example embodiments, the cooling module 300 may cool the optical module 100, for example, the specimen chamber 200 of the optical module 100, through the heat exchange connector 302. The heat exchange connector 302 may continuously cool the specimen chamber 200 by reusing the refrigerant 321 using electrical energy, and thus a preparation time for using the transmission electron microscope 10 may be reduced. In addition, even when a specimen S is brought into or taken out of the specimen chamber 200, a vacuum in the specimen chamber 200 may be easily maintained, and the temperature of the specimen chamber 200 may always be maintained at a low level. Thus, a drift phenomenon caused by introduction of foreign substances into the processing space PS and an increase in the temperature of the processing space PS may be prevented.

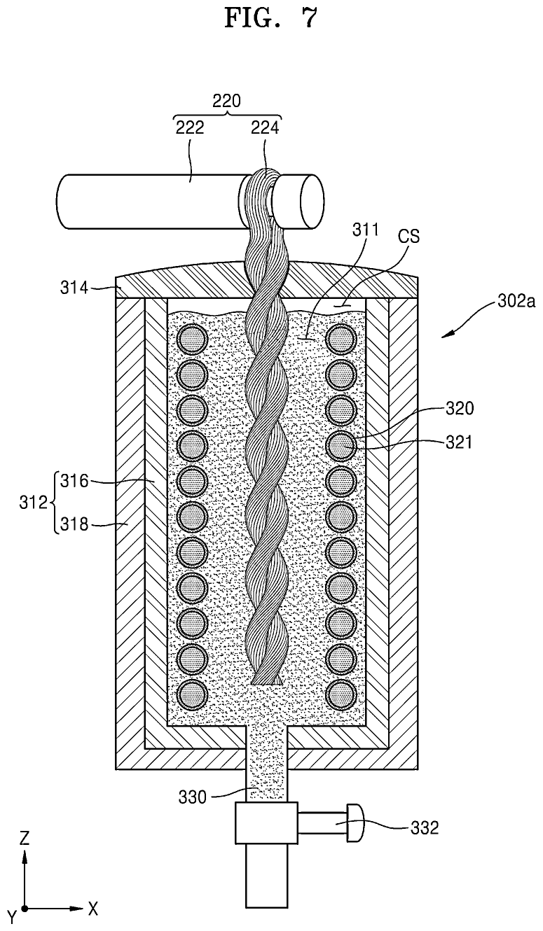

FIG. 7 is a cross-sectional view illustrating a heat exchange connector 302a of the cooling module 300 according to one or more example embodiments. A difference between the one or more example embodiments shown in FIGS. 7 and 6 is whether a heat transfer medium fluid 311 is included in the cooling space CS. In FIG. 7 and in FIGS. 1, 2, 3, 4, 5 and 6, like reference numerals denote like elements, and duplicate descriptions thereof are omitted.

Referring to FIG. 7, the heat transfer medium fluid 311 may be filled in the cooling space CS of the heat exchange connector 302. According to one or more example embodiments, the heat transfer medium fluid 311 may have a lower boiling point than the refrigerant 321 flowing in the heat exchange tube 320 and may fill the cooling space CS in a liquid state.

In one or more example embodiments, the second extension portion 224 of the heat exchange bridge 220 and the heat exchange tube 320 may be immersed in the heat transfer medium fluid 311. According to one or more example embodiments, heat may be transferred by convection from the second extension portion 224 of the heat exchange bridge 220 to the heat exchange tube 320 via the heat transfer medium fluid 311. Therefore, the efficiency of heat exchange between the heat exchange bridge 220 and the heat exchange tube 320 may be improved, while reducing the effect of residual vibration of the heat exchange tube 320 acting on the specimen chamber 200 through the heat exchange bridge 220.

In one or more example embodiments, the pressure of the cooling space CS that is affected by variations in the temperature of the cooling space CS may be adjusted by discharging some of the heat transfer medium fluid 311 through the drain pipe 330.

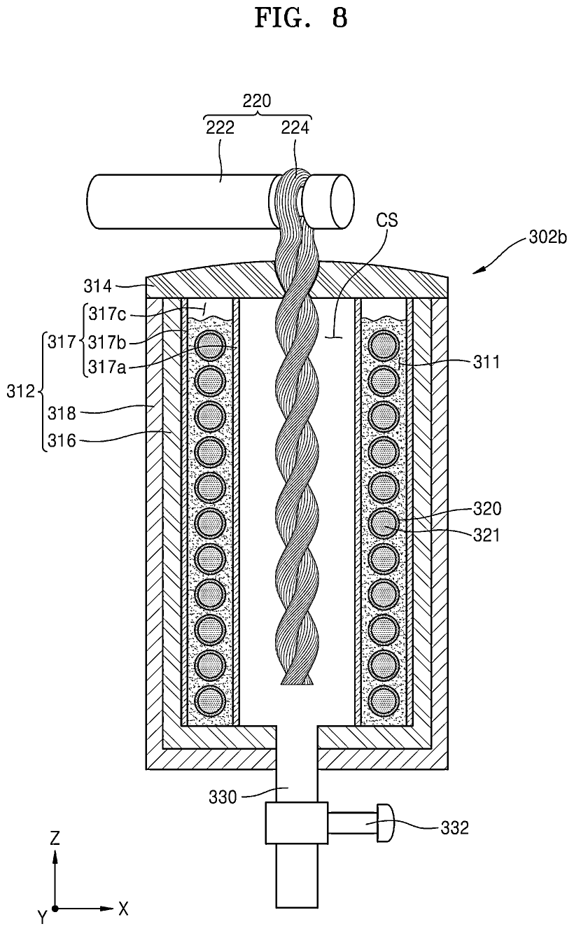

FIG. 8 is a cross-sectional view illustrating a heat exchange connector 302b of the cooling module 300 according to one or more example embodiments. A difference between the one or more example embodiments shown in FIGS. 8 and FIGS. 6 and 7 is whether the housing 312 includes a cooling cylinder 317 configured to accommodate the heat exchange tube 320 therein. In FIGS. 8 and 1, 2, 3, 4, 5, 6 and 7, like reference numerals denote like elements, and duplicate descriptions thereof are omitted.

Referring to FIG. 8, the housing 312 may have a hollow cylindrical shape and may include the cooling cylinder 317, and the cooling cylinder 317 may include a tube accommodation portion 317c provided by an inner wall 317a and an outer wall 317b. For example, the tube accommodation portion 317c may be a space between the inner wall 317a and the outer wall 317b.

In one or more example embodiments, the outer wall 317b of the cooling cylinder 317 may be in contact with the inner wall of the first container 316 having a cup shape. For example, the first container 316 may surround the outer wall 317b of the cooling cylinder 317, and the second container 318 may surround the outer wall of the first container 316. For example, the cooling cylinder 317 may be provided apart from the second container 318 with the first container 316 therebetween. For example, the cooling cylinder 317 may extend in the vertical direction (Z direction).

In one or more example embodiments, the second extension portion 224 of the heat exchange bridge 220 may be accommodated in the cooling space CS that is provided by the inner wall 317a of the cooling cylinder 317 and a bottom surface of the first container 316. In one or more example embodiments, the heat exchange tube 320 may extend in the vertical direction (Z direction) while spirally winding inside the tube accommodation portion 317c. In one or more example embodiments, because the heat exchange tube 320 is disposed in the tube accommodation portion 317c of the cooling cylinder 317, the second extension portion 224 of the heat exchange bridge 220 may be provided stably apart from the heat exchange tube 320. For example, the second extension portion 224 of the heat exchange bridge 220 may be provided apart from the heat exchange tube 320 with the inner wall 317a of the cooling cylinder 317 therebetween. Therefore, vibration transmitted from the cooler body 304 and remaining in the heat exchange tube 320 may be prevented from being directly transferred to the second extension portion 224.

In one or more example embodiments, the tube accommodation portion 317c may be filled with the heat transfer medium fluid 311. In one or more example embodiments, the heat exchange tube 320 may be immersed in the heat transfer medium fluid 311 in the tube accommodation portion 317c. Therefore, vibration remaining in the heat exchange tube 320 may be dispersed through the heat transfer medium fluid 311, and thus, the heat exchange bridge 220 and the specimen chamber 200 may be less affected by the vibration.

While one or more example embodiments have been particularly shown and described above, it will be apparent to those skilled in the art that various changes in form and details may be made therein without departing from the spirit and scope of the following claims.

What is claimed is:

1. A transmission electron microscope comprising:
a specimen chamber;
a heat exchange bridge extending outward from a side wall of the specimen chamber; and
a heat exchange connector comprising:
a heat exchange tube provided around a first portion of the heat exchange bridge; and
a housing sealing the first portion of the heat exchange bridge and the heat exchange tube from an outside of the heat exchange connector.

2. The transmission electron microscope of claim 1, further comprising a cooler body connected to the heat exchange connector,
wherein the cooler body is configured to:
introduce a refrigerant in a liquid phase into the heat exchange tube, and
condense the refrigerant, which is discharged in a gas phase from the heat exchange tube, into a liquid phase.

3. The transmission electron microscope of claim 1, wherein the heat exchange tube is spirally wound along an inner wall of the housing.

4. The transmission electron microscope of claim 1, wherein the first portion of the heat exchange bridge is spaced apart from the heat exchange tube.

5. The transmission electron microscope of claim 1, further comprising a heat transfer medium fluid provided in the housing,
wherein the first portion of the heat exchange bridge and the heat exchange tube are immersed in the heat transfer medium fluid.

6. The transmission electron microscope of claim 1, wherein the first portion of the heat exchange bridge comprises a metallic coil bundle.

7. The transmission electron microscope of claim 1, further comprising a drain pipe extending through a lower surface of the housing.

8. The transmission electron microscope of claim 1, wherein the housing comprises a first container configured to disperse vibrations transmitted from the heat exchange tube.

9. The transmission electron microscope of claim 1, wherein the housing comprises a second container configured to reduce a transfer of external heat into the housing.

10. The transmission electron microscope of claim 1, further comprising a vacuum pump coupled to the specimen chamber.

11. A transmission electron microscope comprising:
a specimen chamber configured to receive a specimen holder;
a heat exchange bridge comprising:
a first portion protruding from an outer wall of the specimen chamber and extending in a horizontal direction; and
a second portion contacting the first portion and extending in a vertical direction;
a heat exchange connector comprising a cooling cylinder and a housing, wherein the cooling cylinder comprises an inner wall and an outer wall spaced apart from the inner wall, and the housing comprises an inner container provided around the cooling cylinder and an outer container provided around the inner container; and
a heat exchange tube provided in a space between the inner wall of the cooling cylinder and the outer wall of the cooling cylinder,
wherein the second portion of the heat exchange bridge is provided in a cooling space defined by the inner wall of the cooling cylinder.

12. The transmission electron microscope of claim 11, further comprising a heat transfer medium fluid provided in the space between the inner wall of the cooling cylinder and the outer wall of the cooling cylinder,
wherein the heat exchange tube is immersed in the heat transfer medium fluid.

13. The transmission electron microscope of claim 11, wherein the inner container comprises an elastic polymer material, and
wherein the outer container comprises an insulating polymer material.

14. The transmission electron microscope of claim 11, wherein the heat exchange tube extends in the vertical direction while spirally winding in the space between the inner wall of the cooling cylinder and the outer wall of the cooling cylinder.

15. The transmission electron microscope of claim 11, further comprising a drain pipe extending through a lower surface of the housing.

16. The transmission electron microscope of claim 11, further comprising:
a rotary pump configured to discharge air from the specimen chamber; and
an ion absorbing pump configured to adsorb ions from the specimen chamber.

17. A transmission electron microscope comprising:
an optical module comprising:
a column;
a plurality of electromagnetic lenses arranged in a vertical direction within the column; and
a specimen chamber between two adjacent electromagnetic lenses from among the plurality of electromagnetic lenses;
a vacuum module comprising a plurality of vacuum pumps connected to the specimen chamber; and
a cooling module comprising:
a heat exchange connector connected to the specimen chamber; and
a cooler body connected to the heat exchange connector,
wherein the specimen chamber comprises:
a chamber side wall; and
a heat exchange bridge comprising:
a first portion protruding outward from the chamber side wall and extending in a first horizontal direction; and
a second portion connected to the first portion and extending in the vertical direction,
wherein the heat exchange connector comprises:
a housing; and
a heat exchange tube provided in the housing,
wherein the second portion of the heat exchange bridge is provided in a cooling space of the housing, and
wherein the heat exchange tube is provided around the second portion of the heat exchange bridge.

18. The transmission electron microscope of claim 17, wherein the cooler body is configured to introduce a refrigerant in a liquid phase into the heat exchange tube, and
wherein the cooler body is configured to condense the refrigerant, which is discharged in a gas phase from the heat exchange tube, into a liquid phase.

19. The transmission electron microscope of claim 17, further comprising a heat transfer medium fluid provided in the cooling space,
wherein the second portion of the heat exchange bridge and the heat exchange tube are provided in the heat transfer medium fluid.

20. The transmission electron microscope of claim 17, wherein the housing comprises:
an inner container defining the cooling space and configured to disperse vibrations; and
an insulating outer container provided around the inner container.
